(19) United States
(12) Patent Application Publication
(10) Pub. No.: US 2016/0065000 A1
(43) Pub. Date: Mar. 3, 2016

(54) SEMICONDUCTOR DEVICE

(71) Applicant: KABUSHIKI KAISHA TOSHIBA, Minato-ku (JP)

(72) Inventor: Keiji MAEDA, Yokohama (JP)

(73) Assignee: KABUSHIKI KAISHA TOSHIBA, Minato-ku (JP)

(21) Appl. No.: 14/563,128

(22) Filed: Dec. 8, 2014

Related U.S. Application Data
(60) Provisional application No. 62/043,622, filed on Aug. 29, 2014.

(51) Int. Cl. H02J 9/06; G11C 14/00; G11C 5/14; H02J 7/00

(52) U.S. Cl. CPC H02J 9/061; H02J 7/0063; G11C 14/0018; G11C 5/144; G11C 5/148; H02J 7/345

(57) ABSTRACT

According to one embodiment, a semiconductor device includes a board including a controller and a memory, a connecting portion on the board, and a standby power source electrically connected to the connecting portion and removably attached to the board.

### CROSS-REFERENCE TO RELATED APPLICATIONS

This application claims the benefit of U.S. Provisional Application No. 62/043,622, filed Aug. 29, 2014, the entire contents of which are incorporated herein by reference.

### FIELD

Embodiments described herein relate generally to a semiconductor device.

### BACKGROUND

There is provided a semiconductor device having a controller and a memory. This semiconductor device operates with receiving power source supply from a host device.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary block diagram illustrating a configuration of a semiconductor device of a first embodiment.

FIG. 2 is an exemplary block diagram illustrating a configuration of a standby power source circuit part shown in FIG. 1.

FIG. 3 is an exemplary plan view illustrating a main board and a subsidiary board of the first embodiment.

FIG. 4 is an exemplary cross-sectional view illustrating the semiconductor device shown in FIG. 3.

FIG. 5 is an exemplary plan view illustrating the semiconductor device equipped with a first subsidiary board of the first embodiment.

FIG. 6 is an exemplary plan view illustrating the semiconductor device equipped with a second subsidiary board of the first embodiment.

FIG. 7 is an exemplary plan view illustrating the semiconductor device equipped with a third subsidiary board of the first embodiment.

FIG. 8 is an exemplary block diagram illustrating the semiconductor device equipped with a connection component of the first embodiment.

FIG. 9 is an exemplary block diagram illustrating a semiconductor device of a second embodiment.

FIG. 10 is an exemplary block diagram illustrating a configuration of a standby power source circuit part shown in FIG. 9.

### DETAILED DESCRIPTION

Various embodiments will be described hereinafter with reference to the accompanying drawings.

In general, according to one embodiment, a semiconductor device comprises a board comprising a controller and a memory, a connecting portion on the board, and a standby power source electrically connected to the connecting portion and removably attached to the board.

In this specification, some components are expressed by two or more terms. These terms are merely examples and the above-mentioned components may be expressed by another or other terms. The other components, which are not expressed by two or more terms, may be expressed by another or other terms.

Also, the drawings are merely examples, and may differ from when the embodiments are actually realized in terms of, for example, the relationship between thickness and planar dimension and the ratio of thickness of layers. Further, in the drawings, the relationship or ratio of dimensions may be different from figure to figure.

### First Embodiment

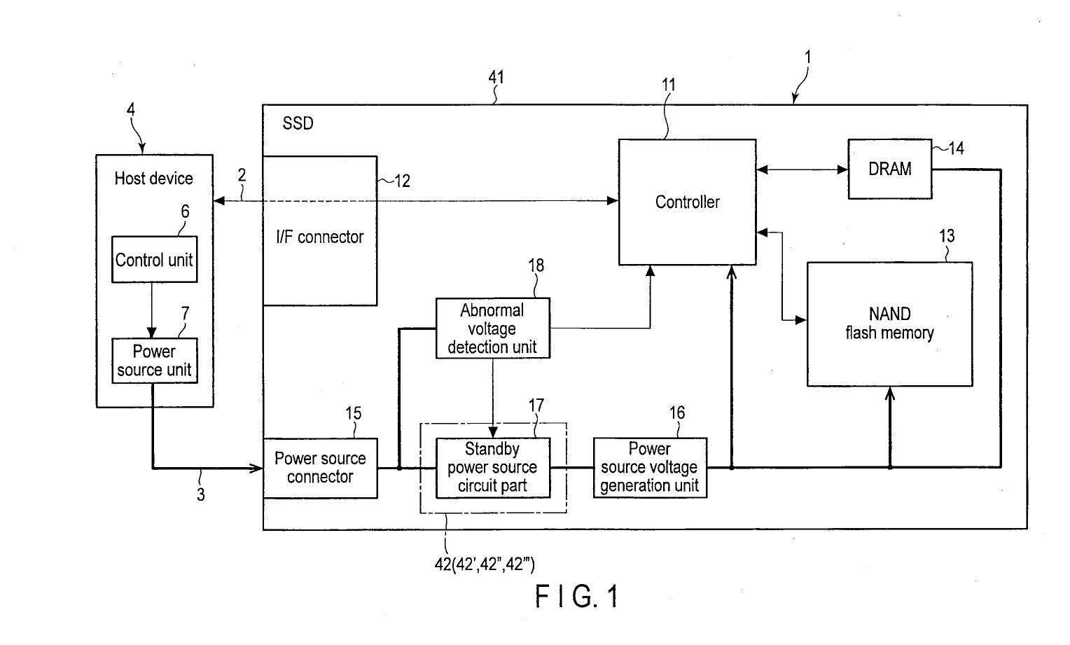

FIG. 1 is a block diagram illustrating a semiconductor device 1 (e.g., memory system) of the first embodiment. The semiconductor device 1 is, for example, a semiconductor storage device. One of the examples is a solid-state drive (SSD). Note that a semiconductor device to which the present embodiment is applicable is not limited thereto.

The semiconductor device 1 is to be connected to a host device 4 (i.e., electronic device or information processing device) via an interface 2 and a power source line 3. The host device 4 may be an appropriate one of various types of electronic devices such as a personal computer, a CPU core, or a server to be connected to a network.

The host device 4 comprises a control unit 6 and a power source unit 7 (e.g., power source circuit). The control unit 6 controls each type of operation of the host device 4. Also, the control unit 6 performs data access control to the semiconductor device 1 and performs write, read and deletion of data to the semiconductor device 1, for example, by transmitting a write request, a read request and a deletion request to the semiconductor device 1. The power source unit 7 provides a power source used in the semiconductor device 1. In this specification, the host device 4 (or the power source unit 7) is an example of an “external power source.”

As shown in FIG. 1, the semiconductor device 1 comprises a controller 11 (i.e., storage controller), an interface connector (I/F connector) 12, a plurality of nonvolatile memories 13, a volatile memory 14, a power source connector 15, a power source voltage generation unit 16 (i.e., power source unit), a standby power source circuit part 17 and an abnormal voltage detection unit 18.

The controller 11 performs overall control for the operation of the semiconductor device 1. The controller 11 controls the plurality of nonvolatile memories 13 and the volatile memory 14 (e.g., performs access control). That is, the controller 11 controls write, retention, read and deletion of data to the plurality of nonvolatile memories 13 and the volatile memory 14.

The controller 11 is to be connected to the host device 4 via the interface connector 12 and the interface 2. The interface 2 is, for example, a serial advanced technology attachment (SATA), a peripheral component interconnect express (PCIe), a serial attached SCSI (SAS) or a universal serial bus (USB), but is not limited thereto.

The nonvolatile memory 13 is a non-temporal memory where data does not get lost even when a power source is disconnected. The nonvolatile memory 13 stores user data managed in the host device 4 and stores management information managed in the volatile memory 14 for backup. The nonvolatile memory 13 is, for example, a NAND flash memory.

The volatile memory 14 is, for example, a dynamic random access memory (DRAM). The volatile memory 14 is used as a storage unit for data transfer, management information recording, and working region. Specifically, the volatile memory 14, as a storage unit for data transfer (e.g., a buffer for data transfer), temporarily stores write data received from the host device 4 before writing it to the nonvolatile memories 13, and temporarily stores read data read from the nonvolatile memories 13 before transmitting it to the host device 4.

Also, the volatile memory 14, as a storage unit for management information recording, stores the management information of the nonvolatile memories 13 (including information for managing the storage locations of data stored in the nonvolatile memories 13, and information for managing the states of the storage regions of the nonvolatile memories 13).

The power source voltage generation unit 16 (e.g., power source circuit or power source voltage generation circuit) generates a predetermined voltage corresponding to each of the storage controller 11, the nonvolatile memories 13 and the volatile memory 14 from a power source supplied to the power source voltage generation unit 16, and supplies the power source to each of the storage controller 11, the nonvolatile memories 13 and the volatile memory 14. For example, the power source voltage generation unit 16 provides a power source of 1.1V (V1) for the controller 11, a power source of 1.8V (V2) for the volatile memory 14, and a power source of 3.3V (V3) for the nonvolatile memories 13.

In the present embodiment, the power source voltage generation unit 16 is to be electrically connected to the power source unit 7 of the host device 4 via the standby power source circuit part 17 and the power source connector 15. The power source voltage generation unit 16 is supplied with a necessary power source from the host device 4 at a normal time (i.e., when the host device 4 operates normally).

Next, the abnormal voltage detection unit 18 and the standby power source circuit part 17 will be described. Note that the host device 4 is hereinafter referred to as external power source 4.

As shown in FIG. 1, the abnormal voltage detection unit 18 (e.g., abnormal voltage detection circuit) is electrically connected to a power line between the power source connector 15 and the power source voltage generation unit 16, and is to be connected to the external power source 4 via the power source connector 15. The abnormal voltage detection unit 18 is an example of a “detection unit” and a “power source abnormality detection unit,” respectively. The abnormal voltage detection unit 18 monitors the state of a power source (e.g., state of voltage) supplied from the external power source 4 to detect abnormal disconnection when the power source supply from the external power source 4 is abnormally disconnected.

Note that “abnormal disconnection” in this specification means that power source supply from the external power source 4 is stopped during the operation of an electronic component or electronic components of the semiconductor device 1 (e.g., the controller 11 and the nonvolatile memories 13). Note that the “detection unit” or the “power source abnormality detection unit” may detect abnormal disconnection by monitoring a state other than a voltage.

As shown in FIG. 1, the standby power source circuit part 17 (e.g., standby power source circuit) is electrically connected, for example, in series between the power source connector 15 and the power source voltage generation unit 16 (i.e., between the external power source 4 and the power source voltage generation unit 16). The standby power source circuit part 17 is also electrically connected to the abnormal voltage detection unit 18 to receive a signal (e.g., detection signal) from the abnormal voltage detection unit 18 when the abnormal voltage detection unit 18 detects the above-mentioned abnormal disconnection.

When the abnormal voltage detection unit 18 detects the above-mentioned abnormal disconnection, the standby power source circuit part 17 temporarily supplies the power source voltage generation unit 16 with a necessary power source instead of the external power source 4 and operates the semiconductor device 1 for a predetermined time in order to protect information being processed.

Specifically, when the power source supply from the external power source 4 is abnormally disconnected, the power source voltage generation unit 16 generates the above-mentioned predetermined voltage corresponding to each of the storage controller 11, the nonvolatile memories 13 and the volatile memory 14 from the power source supplied by the standby power source circuit part 17 to supply the power source to each of the storage controller 11, the nonvolatile memories 13 and the volatile memory 14.

The controller 11 thereby operates by receiving the power source supply from the standby power source circuit part 17 and performs control to save, for example, data stored in the volatile memory 14 (e.g., write data and management information being stored temporarily) to the nonvolatile memories 13. That is, the controller 11 changes the semiconductor device 1 from a normal operation to an emergent operation for protecting information and safely saves half-written information, etc., to the nonvolatile memories 13 when the standby power source operates.

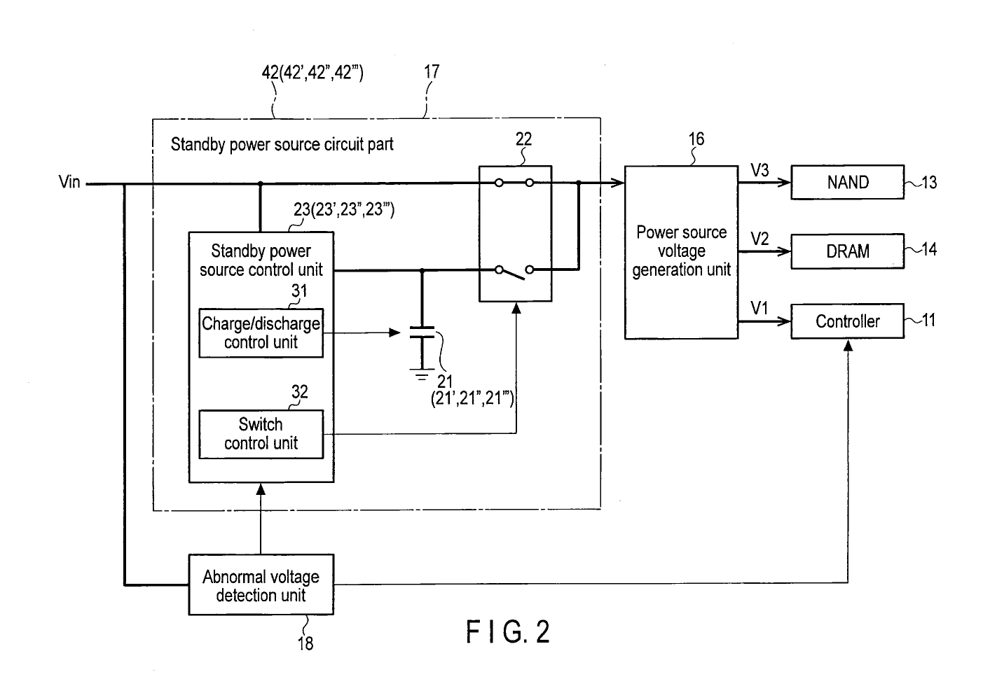

FIG. 2 is a block diagram illustrating a configuration of the standby power source circuit part 17. The standby power source circuit part 17 comprises a standby power source 21, a switch unit 22 and a standby power source control unit 23. The standby power source 21 supplies a power source to the power source voltage generation unit 16 when power source supply from the external power source 4 is abnormally disconnected. The standby power source 21 of the present embodiment is, for example, one of various types of capacitors, and is charged by the power supply source from the external power source 4. Note that the standby power source 21 is not limited to a capacitor but may be a battery, for example.

The switch unit 22 is electrically connected between the external power source 4 and the standby power source 21, and the power source voltage generation unit 16. The switch unit 22 connects the external power source 4 and the power source voltage generation unit 16 when the external power source 4 normally operates. On the other hand, the switch unit 22 connects the standby power source 21 and the power source voltage generation unit 16 when power source supply from the external power source 4 is abnormally disconnected. An example of the switch unit 22 is constituted by a field effect transistor (FET).

The standby power source control unit 23 (e.g., standby power source control circuit) comprises a charge/discharge control unit 31 and a switch control unit 32. The charge/discharge control unit 31 (e.g., charge/discharge control circuit) transmits a control signal to the standby power source 21 to control charge and discharge of the standby power source 21. Specifically, the charge/discharge control unit 31 performs control to charge the standby power source 21 by a power source supplied from the external power source 4 when the external power source 4 normally operates. On the other hand, the charge/discharge control unit 31 performs control to discharge the standby power source 21 when the power source supply from the external power source 4 is abnormally disconnected. The switch control unit 32 (e.g., switch control circuit) transmits a control signal to the switch unit 22 to switch the connection state of the switch unit 22.

Subsequently, an example of an operation of the above-mentioned standby power source circuit part 17 will be described. To begin with, a power source is supplied from the external power source 4 to the standby power source circuit part 17 when the external power source 4 normally operates. The charge/discharge control unit 31 controls the standby power source 21 to be charged by the power source supplied from the external power source 4. The switch control unit 32 connects the external power source 4 and the power source voltage generation unit 16. The power source voltage generation unit 16 thereby generates a necessary voltage from the power source supplied from the external power source 4 and supplies a necessary power source to each of the storage controller 11, the nonvolatile memories 13 and the volatile memory 14.

On the other hand, when the power source supply from the external power source 4 is abnormally disconnected, the abnormal voltage detection unit 18 detects the abnormal disconnection of the external power source 4 to transmit the detection signal to the standby power source control unit 23. After receiving the above-mentioned signal from the abnormal voltage detection unit 18, the standby power source control unit 23 transmits a control signal to the switch unit 22 so as to connect the standby power source 21 and the power source voltage generation unit 16, and transmits a control signal to the standby power source 21 so as to start discharging. The power source voltage generation unit 16 is thereby supplied with a power source from the standby power source 21. The power source voltage generation unit 16 generates a necessary voltage from the power source supplied from the standby power source 21 and supplies a necessary power source to each of the controller 11, the nonvolatile memories 13 and the volatile memory 14.

Then, a mounting structure of the semiconductor device 1 of the present embodiment will be described.

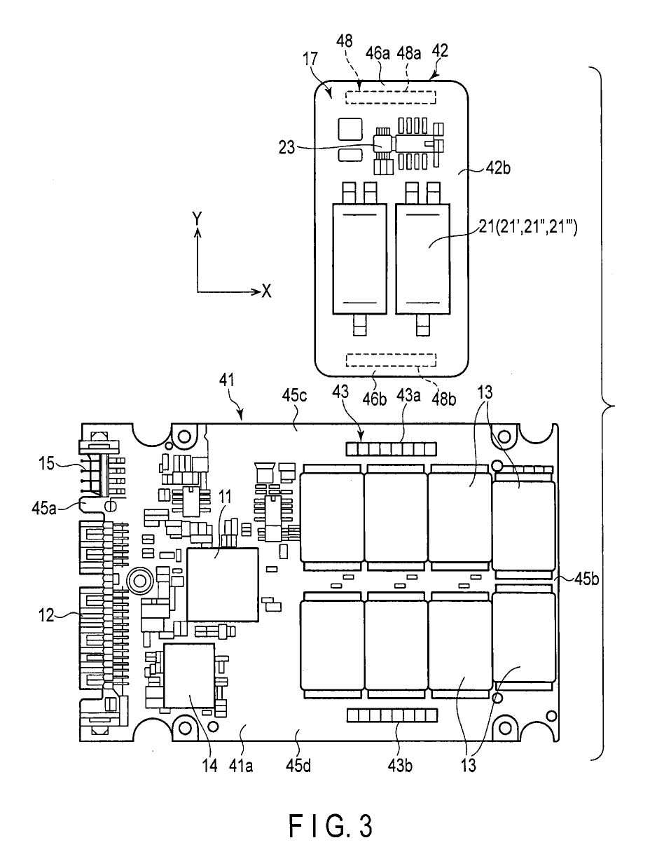

FIG. 3 illustrates the semiconductor device 1 with a subsidiary board 42 removed from a main board 41. As shown in FIG. 3, the semiconductor device 1 comprises the main board 41, the subsidiary board 42 and a connector 43. The main board 41 is an example of a “first board.” The main board 41 is formed in a rectangular plate shape and comprises the controller 11, the interface connector 12, the plurality of nonvolatile memories 13, the volatile memory 14, the power source connector 15, the power source voltage generation unit 16 and the abnormal voltage detection unit 18.

The X-direction and the Y-direction are defined as follows. Both the X- and Y-directions are directions along the main surface (i.e., mounting surface) of the main board 41. The X-direction is the longitudinal direction of the main board 41. The Y-direction is a direction intersecting (e.g., substantially orthogonal to) the X-direction.

The main board 41 comprises first to fourth end portions 45a, 45b, 45c and 45d. The first end portion 45a and the second end portion 45b are the end portions of the longitudinal direction of the main board 41. The first end portion 45a is provided with the interface connector 12 and the power source connector 15. The controller 11 and the volatile memory 14 are mounted in a region closer to the first end portion 45a. The second end portion 45b is positioned opposite the first end portion 45a. The plurality of nonvolatile memories 13 are mounted in a region closer to the second end portion 45b. In the present embodiment, all of the nonvolatile memories 13 are mounted on the main board 41. That is, none of the nonvolatile memories 13 are mounted on the subsidiary board 42.

The third end portion 45c and the fourth end portion 45d are the end portions in the Y-direction, extending between the first end portion 45a and the second end portion 45b. The connector 43 comprises, for example, a pair of first connector portion 43a and second connector portion 43b. The first connector portion 43a is provided in the third end portion 45c of the main board 41, extending substantially parallel to the third end portion 45c. The second connector portion 43b is provided in the fourth end portion 45d of the main board 41, extending substantially parallel to the fourth end portion 45d.

Specifically, the first connector portion 43a and the second connector portion 43b are located separately on both sides of the plurality of nonvolatile memories 13. The first connector portion 43a and the second connector portion 43b extend in the X-direction, for example, to a larger extent than one or more of the nonvolatile memories 13 (or controller 11).

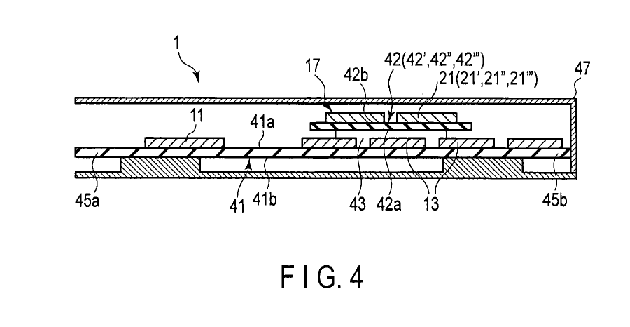

FIG. 4 is a cross-sectional view of the semiconductor device 1. The main board 41 comprises a first surface 41a and a second surface 41b, which is located opposite the first surface 41a. The controller 11, the plurality of nonvolatile memories 13, the volatile memory 14 and the connector 43 are mounted on the first surface 41a of the main board 41.

The subsidiary board 42 is an example of a “second board.” As shown in FIG. 3, the subsidiary board 42 is formed in a rectangular plate shape and comprises the above-mentioned standby power source circuit part 17 (i.e., the standby power source 21, the switch unit 22 and the standby power source control unit 23). In other words, the subsidiary board 42 is a region encircled by a dashed line in FIG. 2 and extracted as another board. The standby power source 21 supplies a power source to the main board 41 when power source supply from the external power source 4 to the main board 41 is disconnected.

The subsidiary board 42 is connected to both the first connector portion 43a and the second connector portion 43b and is electrically connected to the main board 41 via at least either of the first connector portion 43a or the second connector portion 43b. Two end portions 46a and 46b of the subsidiary board 42 are supported by the first connector portion 43a and the second connector portion 43b. The longitudinal direction of the subsidiary board 42 is along the Y-direction. That is, the first connector portion 43a and the second connector portion 43b support both the end portions 46a and 46b in the longitudinal direction of the subsidiary board 42.

The connector 43 is an example of a “connecting portion.” Note that the connector 43 may comprise only either of the first connector portion 43a or the second connector portion 43b so that the subsidiary board 42 is supported by either of the first connector portion 43a or the second connector portion 43b. Also, the subsidiary board 42 may be electrically connected to the main board 41 by, for example, a flexible wiring board instead of a connector. In this case, a flexible wiring board is an example of the “connecting portion.”

As shown in FIG. 4, the subsidiary board 42 comprises a first surface 42a which faces the main board 41 and a second surface 42b which is located opposite the first surface 42a. The semiconductor device 1 comprises a housing 47 which accommodates the main board 41 and the subsidiary board 42. The second surface 42b of the subsidiary board 42 faces the inner surface of the housing 47. The standby power source 21 and the standby power source control unit 23 are mounted on the second surface 42b of the subsidiary board 42. The first surface 42a of the subsidiary board 42 is provided with a connecting portion 48 which is connected to the connector 43 of the main board 41. The connecting portion 48 comprises a first connecting portion 48a which is connected to the first connector portion 43a and a second connecting portion 48b which is connected to the second connector portion 43b. The first surface 42a of the second board 42 has no component which is thicker than the first standby power source 21 except the connecting portion 48a and 48b (i.e., connecting structure for the connector 43).

As shown in FIG. 4, the controller 11 and the volatile memory 14 are located in a region of the main board 41, which is closer to the first end portion 41a than to the second end portion 41b. On the other hand, the connector 43 (i.e., the subsidiary board 42) is located in a region of the main board 41, which is closer to the second end portion 41b than to the first end portion 41a. In this structure, the standby power source 21 is likely to receive less heat from the controller 11 than when the connector 43 (i.e., the subsidiary board 42) is located in a region of the main board 41, which is closer to the first end portion 41a than to the second end portion 41b.

Next, the specification of the subsidiary board 42 will be described.

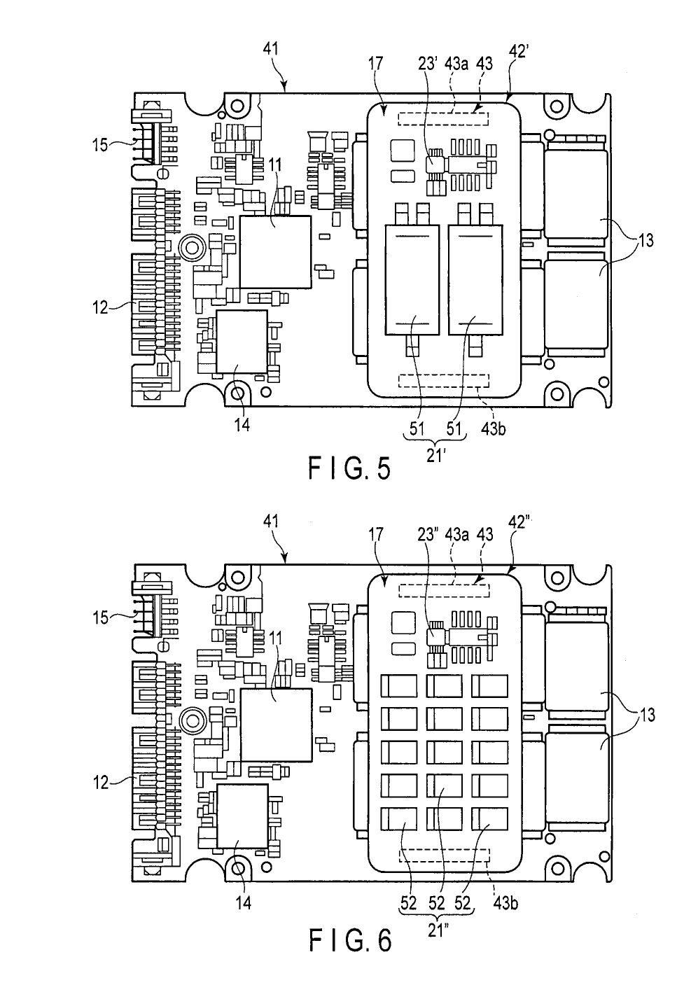

As shown in FIGS. 5 to 7, the semiconductor device 1 of the present embodiment is capable of selecting and equipping, for example, any one of first to third subsidiary boards 42′, 42″ and 42′″ as the subsidiary board 42 according to a desirable specification. That is, each of the first to third subsidiary boards 42′, 42″ and 42′″ is an example of a “third board”, and comprises the standby power source circuit part 17 which includes the standby power source 21, the switch unit 22 and the standby power source control unit 23. In the following, a structure having the same or a similar function will therefore be indicated with the same reference number or the same reference number with one or more primes appended. On the first to third subsidiary boards 42′, 42″ and 42′″, at least either the characteristics or capacity (i.e., electrical capacity) of the equipped standby power source 21 differs from each other, and the connecting portion 48 (e.g., connecting pin) to the connector 43 has a common specification. That is, the first to third subsidiary boards 42′, 42″ and 42′″ are compatible.

As an example, FIG. 5 illustrates the semiconductor device 1 which is equipped with the first subsidiary board 42′. The first subsidiary board 42′ comprises a first standby power source 21′ and a first standby power source control unit 23′. The first standby power source 21′ includes, for example, a plurality of electrical double-layer capacitors 51 (so-called super capacitor). The first standby power source control unit 23′ includes a charge circuit suitable for the characteristics of the electrical double-layer capacitor 51.

An electrical double-layer capacitor is less expensive than a conductive polymer capacitor and reliable in environment which does not reach a high temperature. Also, an electrical double-layer capacitor has a lower mounting height than an aluminum electrolytic capacitor and is therefore advantageous for thickness reduction. On the other hand, an electrical double-layer capacitor deteriorates badly at a high temperature and is therefore not suitable for use in a high-temperature environment and use for a large semiconductor device.

FIG. 6 illustrates the semiconductor device 1 which is equipped with a second subsidiary board 42″. The second subsidiary board 42″ comprises a second standby power source 21″ and a second standby power source control unit 23″. The second standby power source 21″ includes, for example, a plurality of conductive polymer capacitors 52. One example of the conductive polymer capacitor 52 is a POSCAP (product name). The second standby power source control unit 23″ includes a charge circuit suitable for the characteristics of the conductive polymer capacitor 52.

A conductive polymer capacitor is reliable though more expensive than an electrical double-layer capacitor and an aluminum electrolytic capacitor. In particular, in a high-temperature environment, a conductive polymer capacitor is more reliable than an electrical double-layer capacitor. Also, a conductive polymer capacitor has a lower mounting height than an aluminum electrolytic capacitor and is therefore advantageous for thickness reduction. On the other hand, a conductive polymer capacitor has a flaw of absorbing moisture in the air. Since absorbed moisture causes the increase of pressure of water vapor expansion due to heat stress, a special process is required when the controller 11 and the memories 13 are replaced.

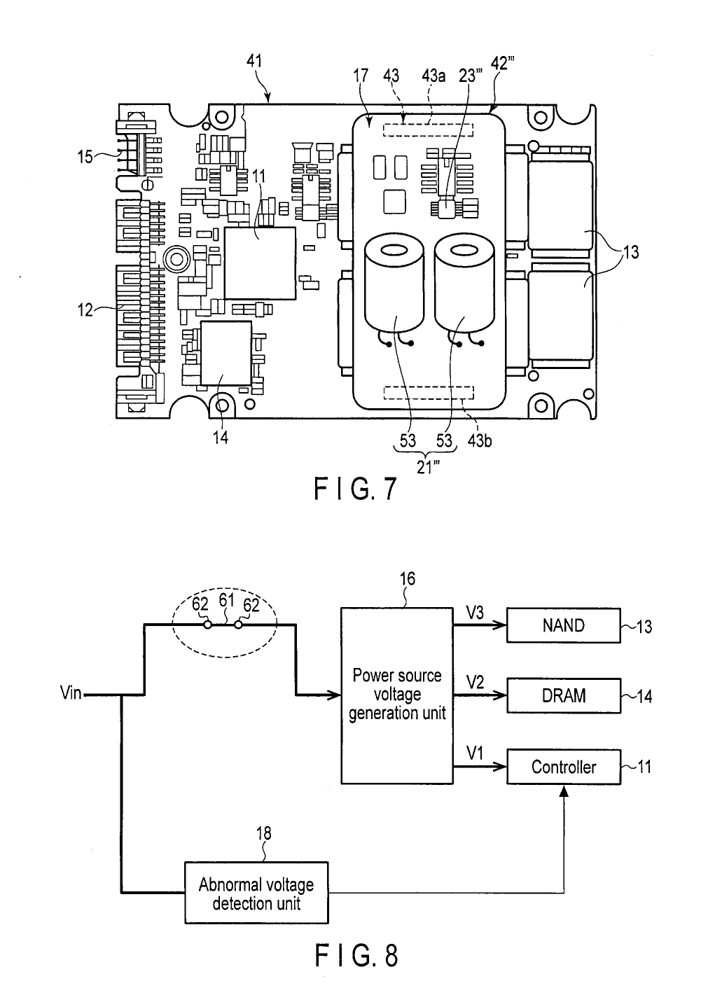

FIG. 7 illustrates the semiconductor device 1 which is equipped with a third subsidiary board 42′″. The third subsidiary board 42′″ comprises a third standby power source 21′″ and a third standby power source control unit 23′″. The third standby power source 21′″ includes, for example, a plurality of aluminum electrolytic capacitors 53. The third standby power source control unit 23′″ includes a charge circuit suitable for the characteristics of the aluminum electrolytic capacitors 53. Note that FIG. 7 schematically illustrates an aluminum electrolytic capacitor.

An aluminum electrolytic capacitor is less expensive than an electrical double-layer capacitor and a conductive polymer capacitor, though disadvantageous in deterioration of its characteristics.

Note the first to third standby power sources 21′, 21″ and 21′″ may have, for example, the same kinds of capacitors and may differ in capacity.

The names of the first to third are given for description in the above and therefore may be called in different orders appropriately.

According to the above-mentioned structure, it is possible to provide the semiconductor device 1, for example, which has a standby power source and prioritizes cost, by selecting the third subsidiary board 42′″ equipped with an aluminum electrolytic capacitor. On the other hand, it is possible to provide the semiconductor device 1, for example, which prioritizes reliability, by selecting the second subsidiary board 42″ equipped with a conductive polymer capacitor. Also, it is possible to provide the semiconductor device 1 which prioritizes both cost and reliability, for example, when used at a low temperature, by selecting the first subsidiary board 42′ equipped with an electrical double-layer capacitor.

FIG. 8 illustrates the semiconductor device 1 equipped with a connection component 61 instead of the subsidiary board 42. That is, the semiconductor device 1 does not comprise the standby power source 21. The connection component 61 is, for example, a jumper element (e.g., jumper chip) or a switch, and directly connects the power source connector 15 and the power source voltage generation unit 16. It is thereby possible to operate the semiconductor device 1 only by means of the main board 41. Note that the main board 41 is provided in advance with a foot print 62 to which the connection component 61 is attachable, for example. It is thereby possible to provide the semiconductor device 1 which further prioritizes cost, when a standby power source is not required.

The above-mentioned semiconductor device 1 has several advantages. In the following, a semiconductor device is taken as a comparative example in which a capacitor used for a standby power source is directly mounted to a board (hereinafter referred to as a main board for description) on which the controller 11 is mounted. In this case, a capacitor used for a standby power source is limited to one kind when designed, and a capacitor of different kinds cannot be selected as a standby power source later.

Also, when the above-mentioned capacitor is mounted to the main board by soldering, it is necessary as to replacement due to performance deterioration to remove the capacitor from the main board by heat wave or soldering iron, to remove and clean the excessive solder on a foot print for soldering of the removed main board, and then to mount a replacement capacitor to remove and clean flux as required. Such a replacement cannot be performed easily.

Further, in a case where a capacitor for a standby power source is mounted on the main board on which a controller and a memory are mounted and when the controller or memory, etc., is replaced for repairing due to malfunction, it is likely that the capacitor receives heat damage which leads to deterioration of its characteristics and decreasing the reliability as a side effect when removing a defective component by means of a heat wave apparatus, etc. For example, in the case of an electrical double-layer capacitor, a maximum acceptable temperature (e.g., 85° C.) is defined for each component, and the product characteristics are not guaranteed when this temperature is exceeded. However, when re-mounting is performed by removing a component on the same board by means of a heat wave apparatus, etc., it is likely that the maximum acceptable temperature of an electrical double-layer capacitor is easily exceeded during the heating process of the replacement.

Furthermore, a conductive polymer capacitor absorbs moisture in the air. Therefore, it is likely that the pressure of water vapor expansion inside a capacitor which absorbs moisture increases due to heat stress when a controller or a memory is replaced and there may be possible that component destruction or deterioration of characteristics occurs.

Still further, when a capacitor for a standby power source is mounted on the main board, it is expected that the board area increases because of its mounting area and that the number of memories equipped is restricted because of the mounting area of the capacitor.

On the other hand, the semiconductor device 1 of the present embodiment comprises the board 41 comprising the controller 11 and the memories 13, a connecting portion (e.g., connector 43) on the board 41, and the standby power source 21 which is electrically connected to the connecting portion and removably attached (i.e., being attachable) to the board 41.

For example, it is possible to select the characteristics and capacity of the standby power source 21, in accordance with an environment where the semiconductor device 1 is used and/or with the priority of cost and reliability. This makes it possible to provide the semiconductor device 1 which meets the individual needs of a user.

In the present embodiment, the semiconductor device 1 comprises the main board 41 comprising the controller 11 and the memory 13, the connector 43 on the main board 41, and the subsidiary board 42 comprising the standby power source 21 which is capable of supplying a power source to the main board 41 when power source supply from the external power source 4 is disconnected.

That is, in the present embodiment, the standby power source 21 for the time of abnormal power source disconnection is provided on the subsidiary board 42, which is a board different from the main board 41 equipped with the controller 11 and the memories 13. The main board 41 and the subsidiary board 42 are electrically connected by the connector 43, etc. It is possible to remove and replace the subsidiary board 42 easily by connection by means of the connector 43, etc. The standby power source 21 of different kinds is mounted on other subsidiary boards 42, respectively. It is thereby possible to optionally select the subsidiary board 42 having the standby power source 21 of different characteristics and to connect the subsidiary board 42 with the main board 41. This makes it possible to provide an optimal information protection method for the time of power supply source disconnection in accordance with the use environment and/or purpose of the semiconductor device 1, in terms of reliability and cost.

Also, according to the above-mentioned structure, it is possible to replace a standby power source by replacing the subsidiary board 42 when the characteristics of a capacitor for a standby power source deteriorate. It is thereby possible to maintain the reliability of the semiconductor device 1.

Further, according to the above-mentioned structure, when the controller 11, the volatile memory 14 or the nonvolatile memories 13 on the main board 41 requires replacement and repair, it is possible to protect a heat-sensitive capacitor from heat damage when replaced and repaired, by temporarily removing the subsidiary board 42 from the main board 41.

In particular, when a capacitor for a standby power source is a conductive polymer capacitor, it is difficult to eliminate moisture once moisture in the air has been absorbed, and reliability is impaired and the capacitor may be destroyed by heat damage when a component is replaced. Therefore, it is necessary to replace the conductive polymer capacitor at the same time when replacing a component such as an IC chip. However, according to the above-mentioned structure, it is possible to avoid heat damage to a conductive polymer capacitor when repaired, by mounting the conductive polymer capacitor on the subsidiary board 42 and removing the subsidiary board 42 during a repair process.

Also, according to the above-mentioned structure, even when it is necessary not only to repair end products but also to repair products in which an IC chip is poorly mounted in the manufacturing process of the semiconductor device 1 in a factory, it is possible to perform repair without considering heat damage to a capacitor for a standby power source. Therefore, it is possible to improve the yield of repair and to reduce the cost.

Further, according to the above-mentioned structure, it is not necessary to arrange a capacitor for a standby power source on the main board 41 by sterically arranging on the main board 41 the subsidiary board 42 which has the standby power source circuit part 17. Therefore, it is possible to reduce the board area of the main board 41 and to increase the number of the nonvolatile memories 13 mounted, as compared when a standby power source circuit is provided on the main board 41. When it is possible to increase the number of the nonvolatile memories 13 mounted, it is possible to provide the semiconductor device 1 which has the standby power source circuit part 17 and has a large storage capacity.

Furthermore, according to the above-mentioned structure, it is possible to select the optimal capacity of a capacitor for a standby power source in terms of cost and reliability, by preparing some the subsidiary boards 42 which differ in capacitor capacity.

In the present embodiment, the main board 41 comprises the controller 11, the nonvolatile memories 13, the nonvolatile memory 14, and the detection unit 18 capable of detecting the abnormal disconnection of power source supply from the external power source 4. The first subsidiary board 42′ comprises the first standby power source 21′, which is removably attached (i.e., being attachable) to the connector 43 and is capable of supplying a power source to the main board 41 when power source supply from the external power source 4 is abnormally disconnected, and the first standby power source control unit 23′, which controls the charge of the second standby power source 21′ and discharges the first standby power source 21′ based on a signal from the detection unit 18. The first subsidiary board 42′ is replaceable with the second subsidiary board 42″ comprising the second standby power source 21″, which is different from the first standby power source 21′, and the second standby power source control unit 23″, which controls the charge of the second standby power source 21″ and discharges the second standby power source 21″ based on a signal from the detection unit 18. According to such a structure, by replacing the subsidiary board 42, it is possible to change the characteristics and/or capacity of the standby power source 21 and to adopt the standby power source control unit 23 suitable for the changed standby power source 21.

In the present embodiment, each of the first standby power source 21′ and the second standby power source 21″ is a capacitor. A capacitor is capable of supplying a large amount of current temporarily, which makes it easier to sufficiently secure a power source necessary for, for example, the controller 11 and the nonvolatile memories 13.

In the present embodiment, the first standby power source 21′ is any one of an electrical double-layer capacitor, a conductive polymer capacitor, and an aluminum electrolytic capacitor. The second standby power source 21″ is any one, which differs from the one of the first standby power source 21′, of an electrical double-layer capacitor, a conductive polymer capacitor, and an aluminum electrolytic capacitor. According to such a structure, it is possible to select an information protection method for the time of abnormal power source disconnection most suitable to use environment and use purpose: for example, select a conductive polymer capacitor when reliability is prioritized; select an aluminum electrolytic capacitor when cost is prioritized although information protection is required for the time of abnormal power source; and select an electrical double-layer capacitor when reliability is prioritized and the cooling function of a system is so sufficient that the semiconductor device 1 does not reach a high temperature.

In the present embodiment, the main board 41 further comprises the power source voltage generation unit 16 which generates from the external power source 4 a voltage corresponding to each of the controller 11, the nonvolatile memories 13 and the volatile memory 14. The first subsidiary board 42′ is electrically connected between the external power source 4 and the power source voltage generation unit 16. According to such a structure, it is possible to share the power source voltage generation unit 16 when a power source is supplied from the external power source 4 and when a power source is supplied from the standby power source 21. It is thereby possible to reduce the number of components necessary for the semiconductor device 1 and to reduce the cost of the semiconductor device 1.

In the present embodiment, it is possible to attach on the main board 41, instead of the first subsidiary board 42′, the connection component 61 which electrically connects the external power source 4 and the power source voltage generation unit 16. According to such a structure, it is possible to easily provide the semiconductor device 1 of a type which is not equipped with the subsidiary board 42. That is, it is possible to select, from the main board 41 of one kind, a type that has no standby power source circuit and a type that has standby power sources of a plurality of capacitor types. It is thereby possible to provide the semiconductor device 1 which further meets the individual needs of a user.

In the present embodiment, the connector 43 includes the first connector portion 43a and the second connector portion 43b. The first connector portion 43a and the second connector portion 43b are located separately at both end portions of the plurality of nonvolatile memories 13 to support the two end portions 46a and 46b of the subsidiary board 42. According to such a structure, the subsidiary board 42 is stably supported by the first connector portion 43a and the second connector portion 43b. It is thereby possible to further increase the reliability of the semiconductor device 1.

In the present embodiment, the two end portions of the subsidiary board 42 which are supported by the first connector portion 43a and the second connector portion 43b are the end portions 46a and 46b in the longitudinal direction of the subsidiary board 42. According to such a structure, it is possible to further improve the stability of the subsidiary board 42 and to further increase the reliability of the semiconductor device 1.

### Second Embodiment

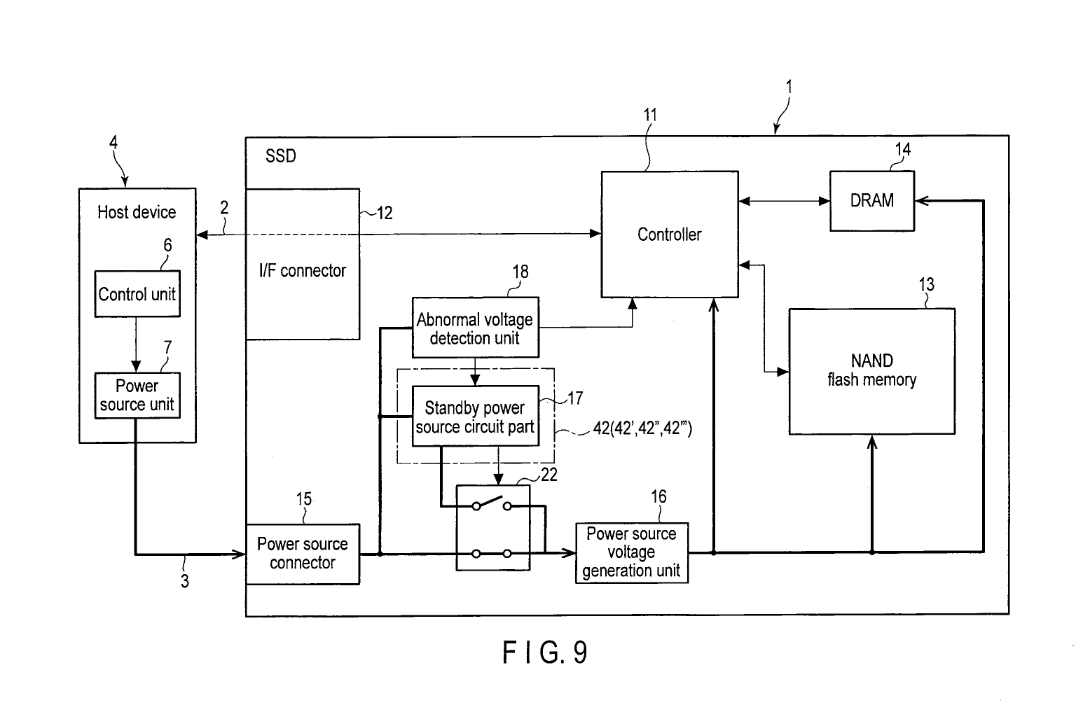

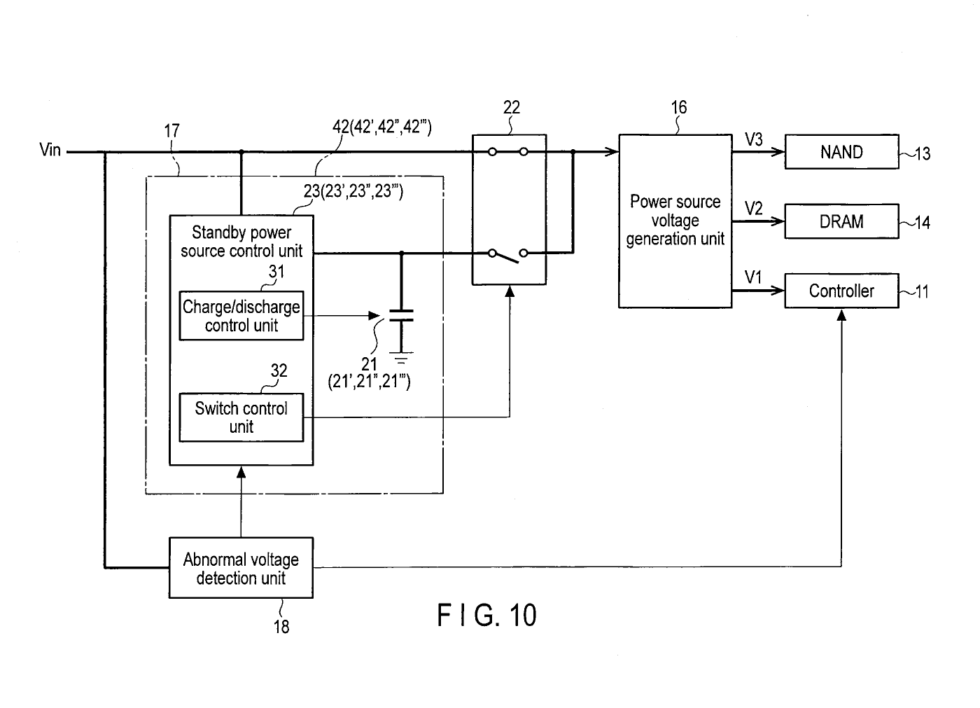

Next, the semiconductor device 1 of the second embodiment will be described with reference to FIGS. 9 and 10. Note that structures having the same or similar functions to the first embodiment will be given the same reference numbers explanations of such structures will be omitted. Also, the structures other than described below are the same as the first embodiment.

In the present embodiment, the switch unit 22 is provided on the main board 41, not on the subsidiary board 42. According to such a structure, it is possible to share the switch unit 22 both when the first subsidiary board 42′ is equipped and when the second subsidiary board 42″ is equipped. It is thereby possible to reduce the number of components necessary for the semiconductor device 1 and to reduce the cost of the semiconductor device 1.

Also, according to the structure of the present embodiment, it is possible to reduce the loss in the connector 43 such as voltage drop since power source supply from the external power source 4 to the power source voltage generation unit 16 does not need to be via the connector 43 which connects the main board 41 and the subsidiary board 42.

While the semiconductor devices 1 of the first and second embodiments have been described above, the embodiments are not limited thereto. For example, the abnormal voltage detection unit 18 may be provided on the subsidiary board 42, not on the main board 41.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first board comprising a controller, a nonvolatile memory and a volatile memory;
a detection unit capable of detecting abnormal disconnection of power source supply from an external power source;
a connector on the first board; and
a second board removably attached to the connector, the second board comprising a first standby power source capable of supplying a power source to the first board when the power source supply from the external power source is abnormally disconnected and a first standby power source control unit which controls a charge of the first standby power source and discharges the first standby power source based on a signal from the detection unit, wherein
the second board is replaceable with a third board removably attachable to the connector, the third board comprising a second standby power source which is different from the first standby power source and a second standby power source control unit which controls a charge of the second standby power source and discharges the second standby power source based on a signal from the detection unit.

2. The device of claim 1, wherein
each of the first standby power source and the second standby power source is a capacitor.

3. The device of claim 1, wherein
the first standby power source is any one of an electrical double-layer capacitor, a conductive polymer capacitor and an aluminum electrolytic capacitor, and
the second standby power source is any one, which differs from the one of the first standby power source, of an electrical double-layer capacitor, a conductive polymer capacitor and an aluminum electrolytic capacitor.

4. The device of claim 1, wherein
the first standby power source and the second standby power source differ in capacity.

5. The device of claim 1, wherein
the first board further comprises a power source voltage generation unit which generates from the external power source a voltage corresponding to each of the controller, the nonvolatile memory and the volatile memory, and
the second board is electrically connected between the external power source and the power source voltage generation unit and the power source voltage generation unit generates from the first standby power source the voltage corresponding to each of the controller, the nonvolatile memory and the volatile memory when the power source supply from the external power source is abnormally disconnected.

6. The device of claim 5, wherein
a connection component which electrically connects the external power source and the power source voltage generation unit is attachable to the first board instead of the second board.

7. The device of claim 5, further comprising a switch unit, wherein
the switch unit is connected between the second board and the power source voltage generation unit and electrically connects the first standby power source and the power source voltage generation unit when the power source supply from the external power source is abnormally disconnected, and
the switch unit is provided on the first board, and connected between the third board and the power source voltage generation unit when the third board is attached instead of the second board.

8. The device of claim 1, wherein
the first board comprises a first end portion and a second end portion,
the controller is located in a region of the first board, which is closer to the first end portion than to the second end portion, and
the connector is located in a region of the first board, which is closer to the second end portion than to the first end portion.

9. The device of claim 1, wherein
the connector comprises a first connector portion and a second connector portion, the first connector portion and the second connector portion being separately located on both sides of the nonvolatile memory to support two end portions of the second board.

10. The device of claim 9, wherein
the two end portions of the second board supported by the first connector portion and the second connector portion are both end portions in a longitudinal direction of the second board.

11. The device of claim 9, wherein
the first connector portion and the second connector portion are separately located in a pair of end portions of the first board, and extends substantially parallel to each of the pair of end portions of the first board.

12. The device of claim 1, wherein
the device comprises a plurality of nonvolatile memories comprising the nonvolatile memory, and
all of the plurality of nonvolatile memories are mounted on the first board.

13. The device of claim 1, wherein
the second board comprising a first surface and a second surface, the first surface facing the first board, and the second surface being opposite to the first surface, and
the first standby power source and the first standby power source control unit are mounted on the second surface of the second board.

14. The device of claim 13, wherein
the first surface of the second board has no component which is thicker than the first standby power source except a connecting structure for the connector.

15. The device of claim 1, wherein
the detection unit is provided on the first board.

16. A semiconductor device comprising:
a first board comprising a controller and a memory;
a connector on the first board; and
a second board removably attached to the connector, the second board comprising a standby power source capable of supplying a power source to the first board when power source supply from an external power source is disconnected.

17. The device of claim 16, wherein
the second board comprises a standby power control unit which charges the standby power source by the power source supply from the external power source.

18. The device of claim 16, wherein
the second board is replaceable with another second board comprising another standby power source which differs from the standby power source at least either in characteristics or capacity.

19. A semiconductor device comprising:
a board comprising a controller and a memory;
a connecting portion on the board; and
a standby power source electrically connected to the connecting portion, the standby power source removably attached to the board.
